(19) United States
(12) Patent Application Publication
(10) Pub. No.: US 2008/0112101 A1
(43) Pub. Date: May 15, 2008

(54) TRANSMISSION LINE FILTER FOR ESD PROTECTION

(76) Inventors: Patrick T. McElwee, Sunnyvale, CA (US); Chinh Huy Doan, Santa Clara, CA (US); Jeffrey M. Gilbert, Palo Alto, CA (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/939,726

(22) Filed: Nov. 14, 2007

Related U.S. Application Data
(60) Provisional application No. 60/859,399, filed on Nov. 15, 2006.

(51) Int. Cl. H02H 7/00; H03H 7/01

(52) U.S. Cl. 361/56; 333/175

(57) ABSTRACT

An integrated circuit chip has on-chip millimeter wave (mmW) circuitry. An on-chip electro static discharge, ESD, protection network couples a signal pad of the chip to the mmW circuitry. The ESD protection network has a shorted stub being a low impedance path to ground for ESD events. Other embodiments are also described and claimed.

This application claims the benefit of the earlier filing date of U.S. Provisional Application Ser. No. 60/859,399 filed Nov. 15, 2006, entitled “Transmission Line Filters for ESD Protection of Millimeter-Wave CMOS Circuits”.

### BACKGROUND

An embodiment is directed to techniques for providing electro static discharge, ESD, protection for millimeter wave electronic circuits.

An important issue with integrated circuit (IC) design and manufacturing is protecting the on-chip components or devices from ESD. ESD is generally understood to refer to the sudden and momentary electric current that flows between two objects at different electrical potentials. In the electronics industry, the term describes momentary unwanted currents that may cause damage to electronic equipment. Examples of ESD events includes sparks caused by static electricity, such as that which can be generated by walking on a rug or removing some types of plastic packaging, or through electrostatic induction, such as when a charged region on the surface of a Styrofoam cup or plastic bag induces potential on a nearby ESD sensitive component. While a spark causes only minor discomfort to people, it leads to severe damage to unprotected integrated circuits such as those made from semiconductor materials, e.g. silicon, and insulating materials such as silicon dioxide. Either of these materials can suffer permanent damage when subjected to the high voltages caused by an ESD event.

ESD prevention can be part of the IC device, where special circuit design techniques are used on the input and output pins of the device. For instance, a diode ESD structure is depicted in FIG. 1 that may be located at the chip boundary (e.g., close to the pads), and that is capable of handling the large currents of an ESD event, to thereby dissipate charge from the signal node quickly. If the charge is allowed to accumulate, the voltage on the signal node may increase to a point where the on-chip devices connected to the signal node are destroyed. The ESD structure as shown in FIG. 1 can provide protection against both positive and negative ESD events (positive beyond the power supply node voltage, and negative beyond the power supply return or ground voltage). It should be noted that, in the case of an ESD event, the charge that is dissipated from the signal node to the on-chip power or ground by the ESD protection circuit can cause the power or ground nodes to increase or decrease to damaging levels. This effect can also damage on-chip devices. For this reason, in practice a “clamp” structure (not shown in the figures) is placed between power and ground nodes in order to limit the maximum potential difference between the two supplies to which the diodes are connected. It is common industry practice to include these “clamp” circuits, in addition to the ESD circuit 102 on a signal pad.

### BRIEF DESCRIPTION OF THE DRAWINGS

The embodiments of the invention are illustrated by way of example and not by way of limitation in the figures of the accompanying drawings in which like references indicate similar elements. It should be noted that references to “an” or “one” embodiment of the invention in this disclosure are not necessarily to the same embodiment, and they mean at least one.

FIG. 1 shows a conventional ESD circuit that uses on-chip diodes.

FIG. 2 shows an ESD network, in accordance with an embodiment of the invention.

FIG. 3 shows an example frequency spectrum of a bandpass ESD network.

FIG. 4 shows a simplified schematic of an example ESD network, in accordance with another embodiment of the invention.

FIG. 5 shows an ESD network that provides a connection for a dc bias generator.

FIG. 6 shows another embodiment of the ESD network.

FIG. 7 shows a block diagram of a system application of an embodiment of the invention.

### DETAILED DESCRIPTION

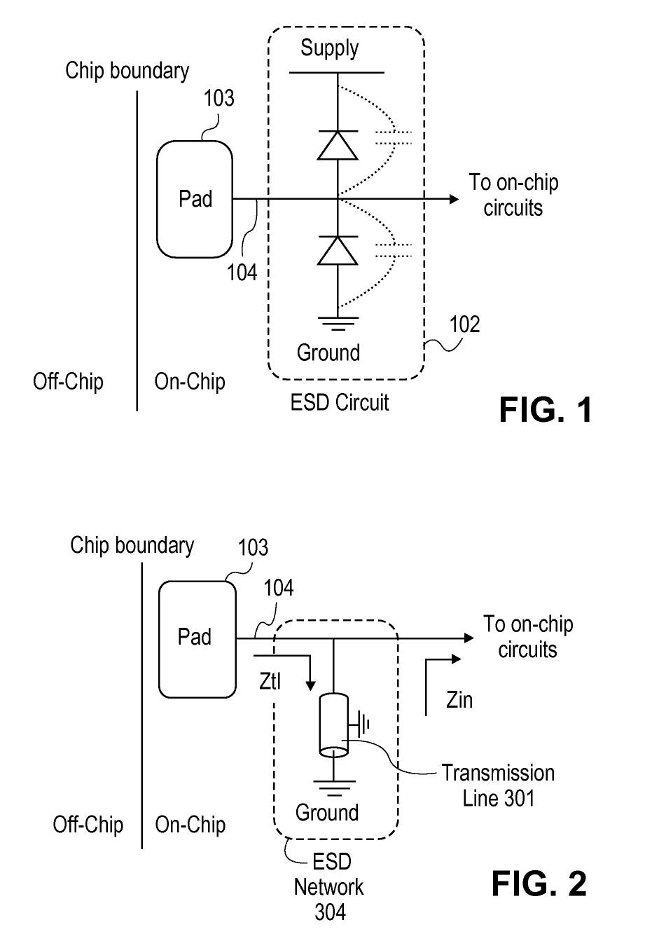

FIG. 1 shows a conventional ESD circuit 102 that uses on-chip diodes. The ESD circuit 102 is coupled between a signal pad 103 and downstream on-chip circuits (not shown). Such an ESD structure adds parasitic capacitances to the signal node 104 that is electrically connected to the pad 103. This additional capacitance acts to decrease the bandwidth of the overall circuit. In many applications, this additional capacitance is small enough that the circuit bandwidth is only minimally affected. For more sensitive designs, ESD circuits comprised of silicon controlled rectifiers (SCRs) and grounded gate n-channel MOSFETs (ggNMOSs) are used which may help reduce the parasitic capacitance that is added to the signal node 104. However, high frequency RF and millimeter wave (mmW) applications, i.e. above 10 GHz, are more sensitive to any additional capacitance. As such, traditional ESD circuits cannot be used in that case.

In accordance with an embodiment of the invention, referring now to FIG. 2, a transmission line filter that includes a shorted transmission line 301 (also referred to as a shorted stub or shorted shunt transmission line) is used as the first on-chip component seen by an external signal. This transmission line filter may be combined with other active and/or passive devices, to form a high pass or band pass network, referred to as an ESD network 304, between the signal pad 103 of the chip and downstream on-chip circuits. The terminology “upstream” and “downstream” used here is only intended to indicate relative signal flow direction and/or relative physical location of devices along a signal path. It should be clear that the ESD networks described here can be used for both input and output pads of an integrated circuit chip.

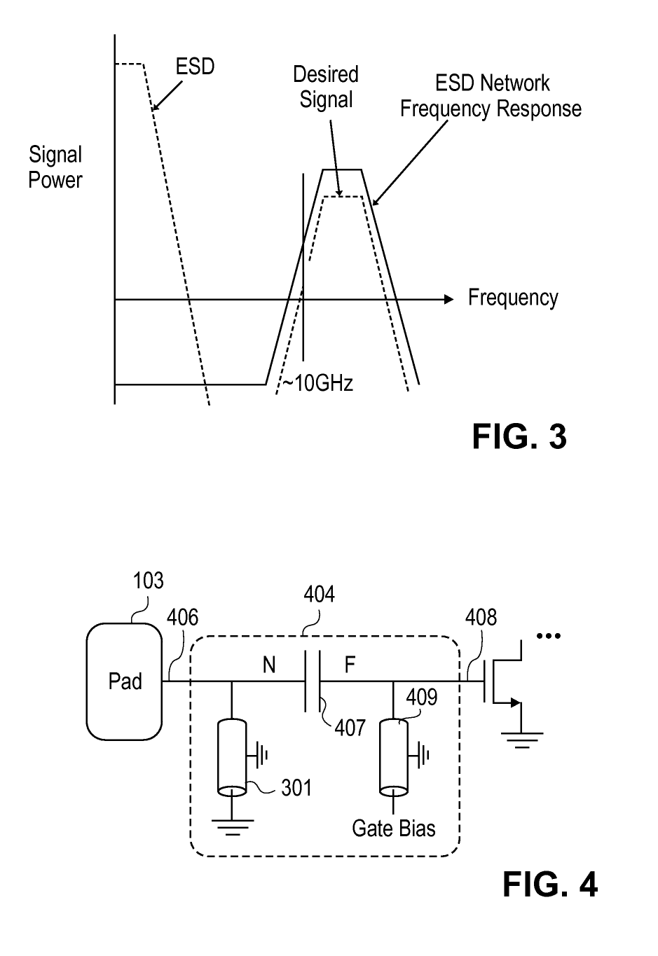

The ESD network 304 passes desired signals from the pad into downstream circuits, while shunting unwanted signals (from the pad) such as an ESD event, to ground, in other words bypassing other circuits that may be directly connected to the protected node (here, node 104), both downstream and upstream of the network 304. FIG. 3 shows an example frequency spectrum of a bandpass ESD network, passing the desired signal while rejecting the ESD event. The lower cutoff frequency of the ESD network's frequency response in this example is about 10 GHz. The strength or ability of the ESD network to shunt the undesired signals to ground, including the steepness and depth of the lower cutoff curve, may be selected to be in accordance with industry standard ESD guidelines. These may be promulgated by, for example, American National Standards Institute (ANSI), JEDEC, or the ESD Association's ESD Guidelines for Human Body Model ESD (HBM), Machine Model ESD (MM), and/or Charged Device Model ESD (CDM).

Returning to FIG. 2, the simplified schematic shows the shunt transmission line 301 as part of the ESD network 304 on the signal node 104, which in this case is electrically connected to signal pad 103 (being either an input pad or an output pad of the chip). In one embodiment, all of these components are on the same chip. Since the energy in an ESD event decreases with increasing frequency, the ESD network 304 should be designed such that the high frequency band of interest, i.e. above 10 GHz, is passed through to the downstream on-chip circuitry, while the lower frequency ESD event, along with other unwanted signal, is shunted to ground and/or a power supply node.

Note that “ground” here refers to any node that serves as a power supply return for the chip, i.e. it need not be at zero Volts. Also, ESD events may cause such a ground to “bounce”, i.e. its voltage may change during an ESD event. It is for this reason, that the additional “clamp” circuitry, described earlier, is typically included.

In the example circuit of FIG. 2, for the calculation of the input impedance of the shorted transmission line 301, the ESD network 304 may be viewed as a one-port device having a single input impedance Ztl. For low frequencies, the frequency dependent impedance looking into the single port of this ESD network 304 (Ztl), from the signal node 104, should be substantially less than the impedance seen looking into any other port that is electrically connected to the signal node 104 (except the port through which the ESD signal is introduced). Thus, in this case, Ztl<Zin (by at least a factor of ten, for instance). This condition should be met at all frequencies that contain potentially harmful ESD content.

In the case where there are multiple ESD sensitive devices connected to the same signal pad, or in the case where the shorted shunt transmission line 301 is located downstream of a port with a sensitive device, so long as the frequency dependent impedance seen looking into the port with the sensitive device is significantly higher than the port that contains the shorted stub, the sensitive device should be protected. For low frequency signals and ESD events, the on-chip, shorted transmission line 301, which has a relatively high impedance Ztl at mmW frequencies, presents a low impedance path to the power supply or return node to which it is connected (in this case, electrically connected to ground). Thus, the shorted transmission line 301 serves at least two purposes, filtering and ESD protection.

FIG. 4 shows a simplified schematic of an example ESD network 404 that, except for the port to which the gate bias is connected, can be thought of as a two-port network. The network 404 provides both filtering and ESD protection, between an upstream port 406 and a downstream port 408. Starting at the upstream port 406, the signal encounters first the shorted shunt transmission line 301, and then the near plate (N) of a series capacitor 407. The latter blocks the dc current generated by a bias voltage generator (not shown, but indicated as “Gate Bias”) from being shorted to ground by the shorted shunt transmission line 301, so that an active circuit downstream of the port 408 can be properly biased. The bias voltage may be delivered by a further piece of transmission line 409 that is dc coupled to the far plate (F) of the capacitor 407. The capacitor 407, the transmission line 409, and the shunted transmission line 301, along with any series transmission lines used to connect these devices together (not shown in the figure), in this case any transmission lines between the pad 103, and the shorted shunt transmission line 301, between elements 301 and 407, between elements 407 and 409, and/or between elements 409 and 408, should be designed so that the ESD network 404 provides a bandpass or highpass frequency response (e.g., as in FIG. 3), in the operating frequency range of the downstream active circuit, e.g. above 10 GHz.

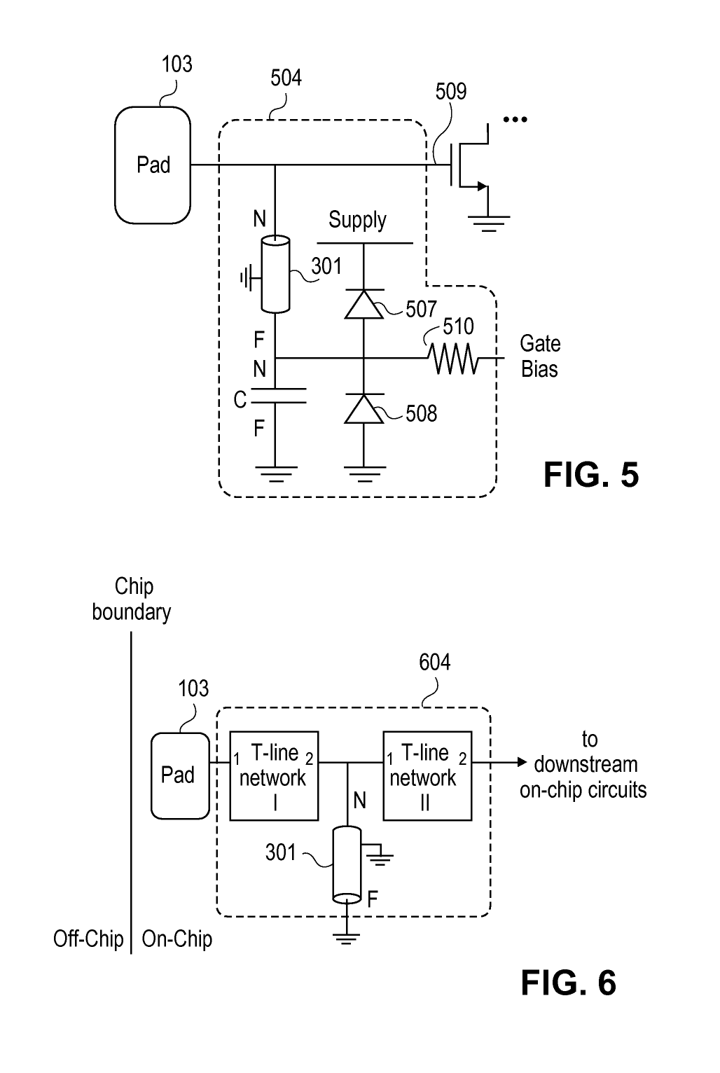

FIG. 5 shows another ESD network 504 where instead of having a direct short to ground or supply, a capacitor and/or diode are coupled to the far end (F) of the transmission line 301. The capacitance presented by the capacitor C, and/or the parasitic capacitance presented by the reverse biased diodes 507 and 508, to the far end of the transmission line 301 effectively creates a short at the higher frequency range (the desired operating range, e.g. above 10 GHz). Thus, at mmW frequencies, the transmission line 301 still looks to be a shorted stub, and can therefore be used to implement the high pass or band pass filter function of the ESD network 504. However during an ESD event, the transmission line 301 is a low impedance path to the diodes 507, 508 which turn on to drain any excess charge off the sensitive node, here node 509. The diodes 507, 508 are connected in an arrangement so that they can limit the positive voltage swing beyond the power supply node voltage, and the negative swing beyond the power supply return or ground voltage, that may be caused by an incoming ESD event through the pad 103. Note that the devices used to limit the voltage need not be limited to diodes. Other devices such as SCRs or ggNMOS devices can also be used. The resistor 510 serves to limit the current through the dc bias generator (Gate Bias). Thus, in addition to providing filtering and ESD protection, the network 504 provides a bias voltage to the protected active circuitry, through the same element (transmission line 301) that performs ESD protection and filtering functions.

Turning now to FIG. 6, the simplified circuit schematic shows an ESD network 604, coupled between the signal pad 103 and ESD sensitive, downstream on-chip circuits. The network 604 includes a first transmission line (T-line) network I having an upstream port (1) and a downstream port (2), the former being coupled to the signal pad 103 upstream of it, via an electrically conductive (dc) path. A second T-line network II has its upstream port (1) dc coupled to the downstream port of T-line network I. Each T-line network has at least a transmission line connecting its upstream and downstream. In addition, it may have one or more stubs, couplers, capacitors, resistors, or active devices as needed to provide the filtering function (e.g., see the frequency response curve in FIG. 3) and any other desired operation. A shorted stub 301 (i.e., shorted to on-chip ground or supply at its far end F) has its near end N dc coupled to the common node shared by the downstream port (2) of T-line network I and the upstream port (1) of T-line network II. As in the embodiment of FIG. 5, at mmW frequencies, the transmission line 301 as a shorted stub assists the network 604 to implement the latter's high pass or band pass filter function. However during an ESD event, the transmission line 301 is a low impedance path to ground, which helps prevent voltage buildup on the sensitive node, here port 2 of T-line network II.

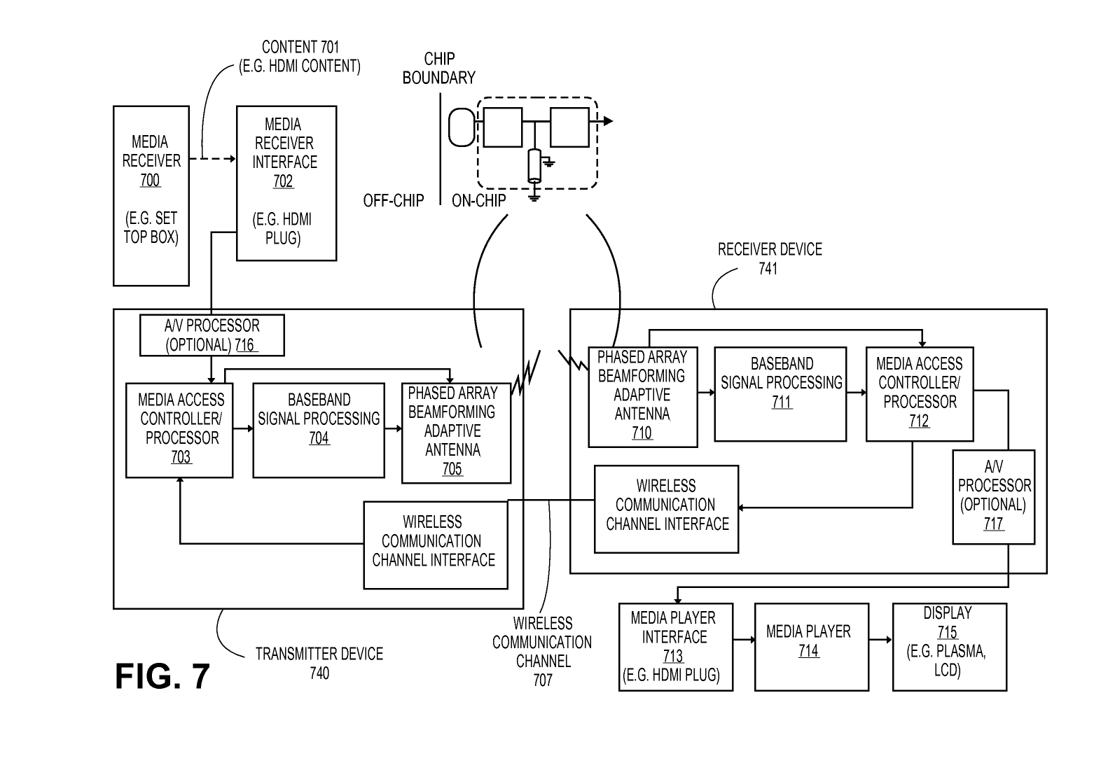

Referring to FIG. 7, a block diagram of a system application of an embodiment of the invention is shown. The ESD networks described here could also be used to protect other types of systems as mentioned below. The wireless communication system shown has a transmitter device 740 with an adaptive beam forming antenna means 705. The antenna means implements a wireless content link to transfer content 701, such as streaming digital audio and/or video, to a receiver device 741. In addition, a separate wired or wireless link (e.g., wireless communication channel 707, also referred to as the side or back link) is provided, to send antenna information. This antenna information is sent back from the receiver device 741 to the transmitter device 740, to enable the transmitter to adapt its antenna array 705 by steering the antenna elements to operate in another direction, for example to avoid obstacles that have appeared between the transmitter and the receiver. The back link may also be used to transfer content protection information, such as encryption keys and acknowledgements of encryption keys, for use in playback of the content received at the receiving device 741. The content link may be in the 60 GHz band, whereas the back link may be in another wireless band, e.g. 2.4 GHz band.

Still referring to FIG. 7, the system has a media receiver 700 that receives digital audio and/or video content from a source, such as a cable television company's cable transmitter or a satellite television provider's satellite. The media receiver 700 may be a set top box. The content 701 may comprise base-band digital video such as content adhering to HDMI or DVI standards. In that case, the media receiver 700 may include an HDMI transmitter to forward the received content. The media receiver sends its content to the transmitter device 740 via a media receiver interface 702. The interface 702 may include logic that converts content into HDMI content. It thus may comprise an HDMI plug, for instance, and in that case the content is sent via a wired connection. Alternatively, the transfer could occur through a wireless connection. In other embodiments, the content comprises DVI content.

As introduced above, transmitter device 740 wirelessly transfers information to the receiver device 741 using two wireless channels. One of the channels is through a phased array antenna with adaptive beam forming (content channel). The other, in this embodiment, is via wireless communications channel 707, also referred to here as the back channel or side channel. Receiver device 741 transfers the content received from transmitter device 740 to a media player 714, via a media player interface 713. This transfer may occur through a wired or wireless connection. For instance, the media player interface 713 may comprise an HDMI plug. Media player 714 causes the content to be played on an audio/video display 715, such as an LCD flat panel television display. The media player 714 may be a DVD player/recorder that can play and/or record the content being received from the transmitter device 740.

The transmitter device 740 comprises an optional audio/video (A/V) processor 716, a media access controller/processor 703, base-band processing component 704, and the phased array antenna means 705. Still referring to FIG. 7, the antenna means 705 has a digitally controlled phased array antenna that is coupled to and controlled by the processor 703, to transmit content to the receiver device 741 using adaptive beam forming. A similar arrangement is also present in the receiver device 741 to receive content from the transmitter device 740 using adaptive beam forming. An embodiment of the invention as described in connection with FIGS. 2-6 may be implemented within the antenna means 705, to protect a chip that is part of the RF transmitter device that drives the antennas. The invention may also be used in an RF receiver device that receives the signal from the antenna, e.g. within one or both of antenna means 705, 710. As an alternative, or in addition, the ESD network may protect a chip that is part of the RF circuitry between the antennas and the phase shifters that are typically used for an antenna array.

In one embodiment, base-band signal processor 704 generates orthogonal frequency division multiplexed (OFDM) signals which are decoded by base-band signal processor 711. In another embodiment, base-band signal processor 704 generates time-domain signal-carrier signals (including OOK, BPSK, QPSK, or QAM signals) which are decoded by base-band signal processor 711.

During initialization of the antennas 705 and 710, the wireless communication link 707 is used to send information that enables processor 703 to select a direction to transmit. This information may include antenna location and antenna performance for that antenna location, which is sent by the processor 712 to the processor 703 to enable the latter to determine which direction to transmit the content. In another embodiment, this information may include phase and/or gain settings. In yet another embodiment, 705 and/or 710 are different types of smart antennas such as sectorized antennas. Further details concerning the system of FIG. 7 can be found in U.S. Patent Application Publication No. 2007/0037528. Other system applications of the ESD circuit include military wireless communications systems, automotive radar systems, and other mmW communication systems which may or may not have phased array antennas.

The invention is not limited to the specific embodiments described above. For example, in the examples given above in FIG. 4 and FIG. 5, the first on-chip downstream circuit that is shown is an insulated gate field effect transistor. Indeed, in many instances, an advanced yet standard complementary metal oxide semiconductor, CMOS, fabrication process, such as a 0.13 micron or smaller process, may be used to implement the chip (including the on-chip ESD networks described). However, the embodiments of the invention described here may alternatively be implemented by other microelectronic fabrication processes, including for example a 0.18 micron, SiGE bipolar CMOS process. Accordingly, other embodiments are within the scope of the claims.

What is claimed is:

1. A circuit comprising:
a signal pad;
a shorted, shunt transmission line on-chip with the signal pad and having a near end coupled to the signal pad, and a far end coupled to power supply or ground, wherein frequency dependent absolute value of impedance looking into the near end is substantially less than the impedance seen looking into any other on-chip port that is coupled to the signal pad except for the port from which an ESD signal is introduced, over a frequency range that lies somewhere above dc and below 10 GHz.

2. The circuit of claim 1 wherein the near end is dc coupled to the signal pad.

3. The circuit of claim 2 wherein the far end is dc coupled to ground.

4. The circuit of claim 2 further comprising a capacitor having a near plate coupled to the near end, and a dc bias generator coupled to a far plate of the capacitor.

5. The circuit of claim 2 further comprising a capacitor having a near plate coupled to the far end and a far plate dc coupled to said ground or power supply.

6. The circuit of claim 5 further comprising:
a first diode coupling the far end to said power supply; and
a second diode coupling the far end to said ground.

7. The circuit of claim 6 further comprising a dc bias generator coupled to the far end.

8. An integrated circuit chip comprising:
a signal pad;
a first transmission line network having a first port and a second port, the first port being coupled to the signal pad;
a second transmission line network having a first port and a second port, its first port being coupled to the second port of the first transmission line network; and
a shorted stub having a near end and a far end, the near end being coupled between the second port of the first transmission line network and the first port of the second transmission line network,
wherein the shorted stub and the first and second transmission line networks are adapted to (1) implement a bandpass or highpass network to pass a desired signal that is somewhere in the range above 10 GHz between the signal pad and the second port of the second transmission line network, and (2) shunt to ground an undesired electro static discharge (ESD) signal that lies somewhere between DC and 10 GHz and that is received at the signal pad.

9. The integrated circuit chip of claim 8 wherein the shorted stub can shunt the undesired ESD signal in accordance with an electronics industry standard for ESD protection.

10. The integrated circuit chip of claim 8 wherein the second transmission line network comprises a series coupled capacitor between its first and second ports.

11. The integrated circuit of claim 10 further comprising a dc bias generator coupled to the second transmission line network at a point downstream of the capacitor.

12. The integrated circuit of claim 8 wherein the shorted stub has its far end dc coupled to said ground.

13. The integrated circuit of claim 8 wherein the shorted stub has its far end ac coupled to said ground via a capacitor that acts as essentially a short at some frequency above 10 GHz.

14. The integrated circuit of claim 13 further comprising:
a first diode coupling the far end of the shorted stub to a power supply node; and
a second diode coupling the far end of the shorted stub to said ground.

15. The integrated circuit of claim 14 further comprising a dc bias generator coupled to the far end of the shorted stub.

16. An integrated circuit chip comprising:
a signal pad;
a first transmission line network having a first port and a second port;
a second transmission line network having a first port and a second port, its first port being coupled to the second port of the first transmission line network; and
a shorted stub having a near end and a far end, the near end being coupled between the second port of the first transmission line network and the first port of the second transmission line network,
wherein a frequency dependent absolute value of impedance looking into the near end of the shorted stub is smaller than a frequency dependent absolute value of impedance looking into the first port of the second transmission line network over a frequency range that lies somewhere above DC and below 10 GHz.

17. The integrated circuit chip of claim 16 wherein a frequency dependent absolute value of impedance looking into the near end of the shorted stub is larger than a frequency dependent absolute value of impedance looking into the first port of the second transmission line network over a frequency range that lies somewhere above 10 GHz.

18. The integrated circuit chip of claim 16 wherein the frequency dependent absolute value of impedance looking into the shorted stub is smaller by at least a factor of ten.

19. An electronic system comprising:
a millimeter wave (mmW) beam forming antenna array having an integrated circuit chip as a component, the chip having a signal pad, on-chip mmW circuitry, and an on-chip electro static discharge, ESD, protection network coupling the signal pad to the mmW circuitry, the ESD protection network having a shorted stub being a low impedance path to ground for ESD events.

20. The electronic system of claim 19 wherein the ESD protection network further comprises:
a first transmission line network having a first port and a second port, the first port being coupled to the signal pad upstream of the second port; and
a second transmission line network having a first port and a second port, its first port being coupled to the second port of the first transmission line network upstream of its second port, wherein
the shorted stub has a near end and a far end, the near end being coupled between the second port of the first transmission line network and the first port of the second transmission line network, and a frequency dependent absolute value of impedance looking into the near end of the shorted stub is smaller than a frequency dependent absolute value of impedance looking into the first port of the second transmission line network over a frequency range that lies somewhere above DC and below 10 GHz.

21. The electronic system of claim 19 wherein a frequency dependent absolute value of impedance looking into the near end of the shorted stub is larger than a frequency dependent absolute value of impedance looking into the first port of the second transmission line network over a frequency range that lies somewhere above 10 GHz.

22. The electronic system of claim 19 wherein the integrated circuit chip has been manufactured by a CMOS process.

23. The electronic system of claim 19 in combination with a consumer product grade audio and/or video digital media receiver, wherein the antenna array is coupled to receive an audio and/or video stream from the media receiver and transmit the stream.

24. The electronic system of claim 19 in combination with a consumer product grade audio and/or video digital media player, wherein the antenna array is coupled to send a received audio and/or video stream to the media player for playback.
